(19) United States
(12) Patent Application Publication
(10) Pub. No.: US 2015/0340368 A1
(43) Pub. Date: Nov. 26, 2015

(54) SEMICONDUCTOR DEVICE MANUFACTURING METHOD

(71) Applicant: PS4 Luxco S.a.r.l., Luxembourg (LU)

(72) Inventor: Hiromitsu Oshima, Tokyo (JP)

(21) Appl. No.: 14/655,674

(22) PCT Filed: Dec. 12, 2013
(86) PCT No.: PCT/JP2013/083308

§ 371 Date: Jun. 25, 2015

(30) Foreign Application Priority Data
Dec. 27, 2012 (JP) 2012-284036

(51) Int. Cl. H01L 27/108; H01L 21/762

(52) U.S. Cl. CPC H01L 27/10891; H01L 21/76224; H01L 27/1085

(57) ABSTRACT

One semiconductor device manufacturing method includes forming, on a principal surface of a semiconductor substrate, multiple active regions which extend in an X-direction within the principal surface and are repeatedly arranged in a Y-direction, forming multiple trenches which extend in the Y-direction and define multiple active regions (silicon pillars) by respectively dividing the multiple active regions in the X-direction, forming element isolation regions by embedding an insulating film in the multiple trenches (T1), forming trenches which extend in the Y-direction after the element isolation regions are formed, and forming word lines by forming a gate insulating film, which covers the inner surfaces of the trenches, and further embedding a conductive film in the trenches. The trenches are formed by means of mutual self-alignment in the X-direction.

### TECHNICAL FIELD

The present invention relates to a method of manufacturing a semiconductor device, and in particular relates to a method of manufacturing a semiconductor device in which word lines, formed embedded in a semiconductor substrate, and element isolation regions extending in the word line direction are formed in mutual self-alignment.

### BACKGROUND ART

In semiconductor devices such as DRAMs (Dynamic Random Access Memory), element isolation regions are provided in the surface of a silicon substrate using STI (shallow trench isolation), and these demarcate a plurality of active regions in a matrix formation. The element isolation regions include first element isolation regions which isolate the active regions in a bit line direction, and second element isolation regions which isolate the active regions in a word line direction. Patent literature article 1 discloses examples of such element isolation regions and active regions.

### PATENT LITERATURE

Patent literature article 1: Japanese Patent Kokai 2012-134395

### SUMMARY OF THE INVENTION

### Problems to be Resolved by the Invention

However, in the semiconductor device described in patent literature article 1, the word lines are formed from a conductive film embedded in the semiconductor substrate, and the word lines (embedded word lines) and the first element isolation regions (element isolation regions extending in the word line direction) are formed in mutual self-alignment. This point will be described in more detail hereinafter. It should be noted that in the following description, the respective widths, in the bit line direction, of the word lines and the first element isolation regions are W1 and W3, conforming with patent literature article 1. Further, the distance in the bit line direction between a certain first element isolation region and the word line closest to said first element isolation region is W2. Further, the distance between two word lines passing through the same active region is W4.

In the method described in patent literature article 1, the substrate of the semiconductor substrate is first covered by a plurality of linear mask patterns, each extending in the word line direction. The width of the linear mask pattern in the bit line direction is 2W2−W3, and the distance between adjacent mask patterns is set to 2W1+W4. First side-wall insulating films having a thickness W1 in the bit line direction are then formed on the sidewalls of the linear mask pattern, and the linear mask pattern is then removed. The first side-wall insulating films formed in this way form a pattern of insulating films covering only the regions in which the word lines are to be embedded. Second side-wall insulating films having a thickness W2 in the bit line direction are then formed on the sidewalls of the first side-wall insulating films, after which the first side-wall insulating films are removed. The second side-wall insulating films formed in this way form a pattern of insulating films having openings exposing the regions in which the element isolation regions are to be embedded, and the regions in which the word lines are to be embedded. Therefore by etching the main surface of the semiconductor substrate, using the second side-wall insulating film as a mask, it is possible to form trenches for embedding each of the element isolation regions and word lines. The word lines and the first element isolation regions are then formed by covering the inner surfaces of the formed trenches with a thin insulating film, and embedding a conductive film in the trenches.

According to the forming method described hereinabove, the respective locations of the word lines and the first element isolation regions in the bit line direction are defined accurately in accordance with the location in which the linear mask pattern, which is formed first, is formed. If, as in this example, the relative locations of two types of embedded film are determined in accordance with the location in which a common pattern is formed, this is described in the present specification as the two types of embedded film being formed in mutual self-alignment.

However, according to the method described in patent literature article 1, not only the word lines, but also the first element isolation regions are formed using the conductive film. First element isolation regions formed in this way employ what is known as electric-field shielding, and in order for these to exhibit an element isolating function, a certain voltage must be applied continuously at all times. A control circuit is therefore required in order to apply this voltage, thereby complicating the circuit.

### Means of Overcoming the Problems

A method of manufacturing a semiconductor device according to one aspect of the present invention is characterized in that it comprises: a step of forming a plurality of first active regions in the main surface of a semiconductor substrate, extending in a first direction in said main surface, and disposed in a repeating manner in a second direction which intersects said first direction; a step of forming a plurality of first trenches, each extending in the second direction and demarcating a plurality of second active regions formed by dividing each of the plurality of first active regions in the first direction; a step of forming first element isolation regions by embedding first insulating films into the plurality of first trenches; a step of forming second trenches, each extending in the second direction, after the first element isolation regions have been formed; and a step of forming second insulating films covering the inner surfaces of the second trenches, and forming wiring lines by embedding conductive films into the second trenches; wherein the first and second trenches are formed in mutual self-alignment, relative to the first direction.

A method of manufacturing a semiconductor device according to another aspect of the present invention is characterized in that it comprises: a step of forming, on the main surface of a semiconductor substrate, a first sacrificial film pattern having linear first opening portions extending in a second direction in said main surface; a step of forming first side-wall insulating films covering the inner walls of the first opening portions; a step of removing the first sacrificial film pattern after the first side-wall insulating films have been formed; a step of forming second side-wall insulating films covering the sidewalls of the first side-wall insulating films; a step of forming first trenches by etching the main surface, using the first and second side-wall insulating films as a mask; a step of forming first element isolation regions by embedding first insulating films into the first trenches; a step of removing the first side-wall insulating films after the first element isolation regions have been formed; a step of forming second trenches by etching the regions of the main surface on which the first side-wall insulating films were formed; and a step of forming word lines by forming second insulating films covering the inner surfaces of the second trenches, and embedding conductive films into the second trenches.

### Advantages of the Invention

According to the present invention, first element isolation regions can be formed using an insulating film while wiring lines (word lines) and first element isolation regions are formed in mutual self-alignment with respect to the first direction. It is thus not necessary to apply a voltage to the first element isolation regions, and the circuit can therefore be simplified.

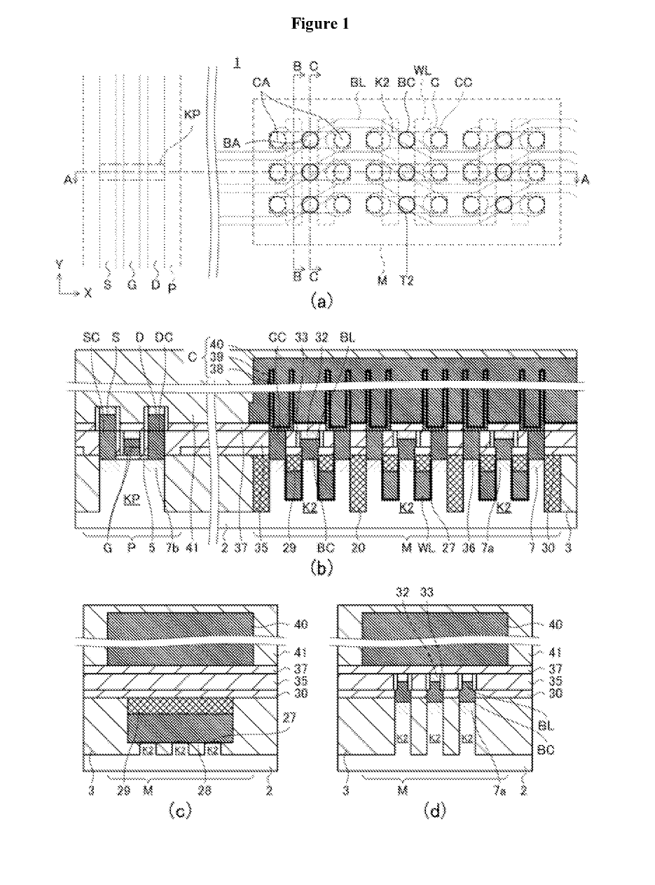

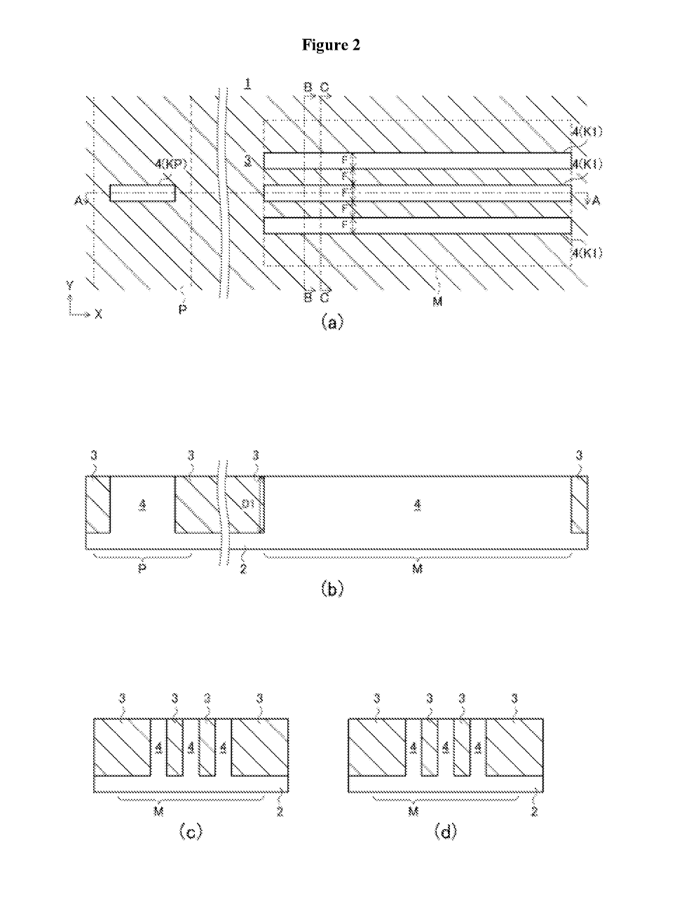

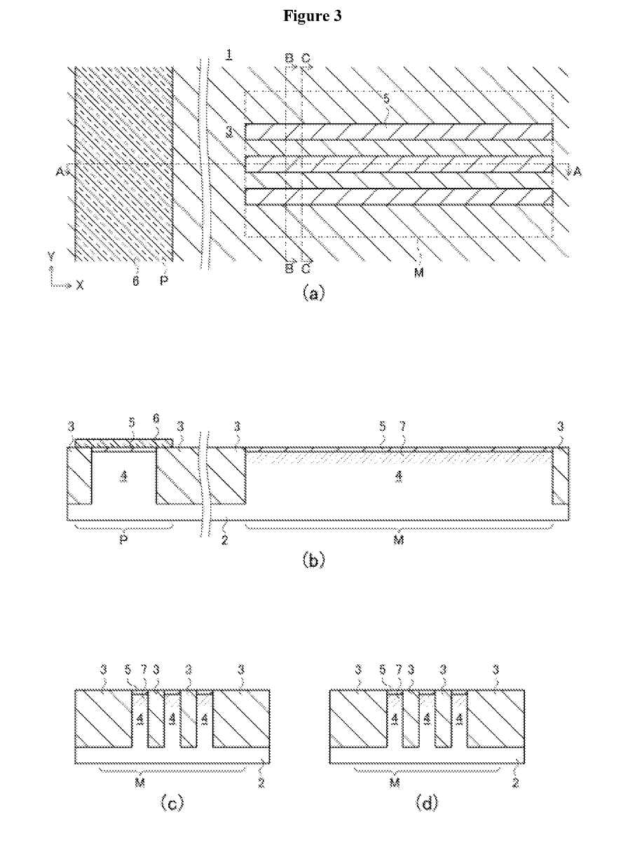

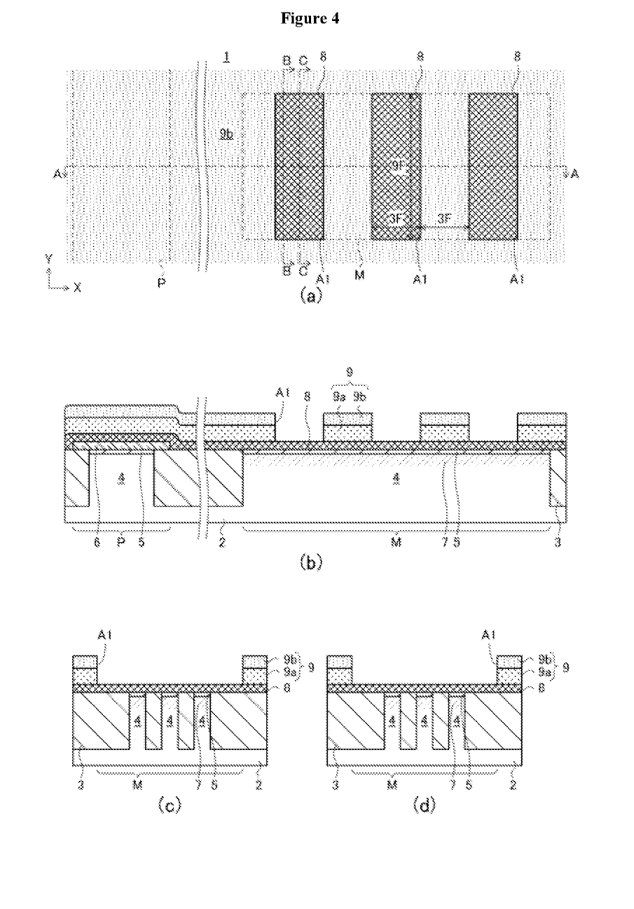

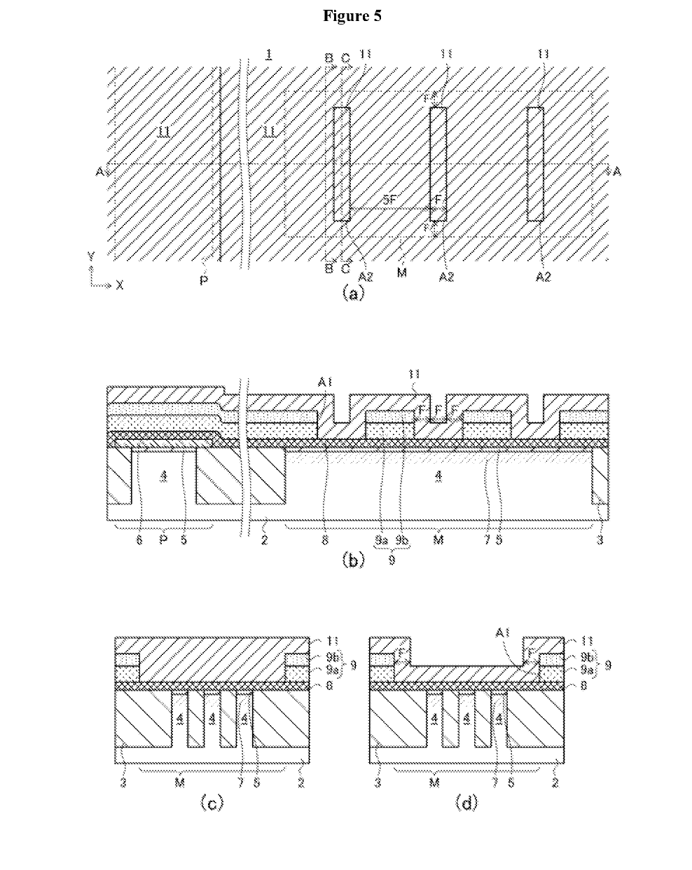

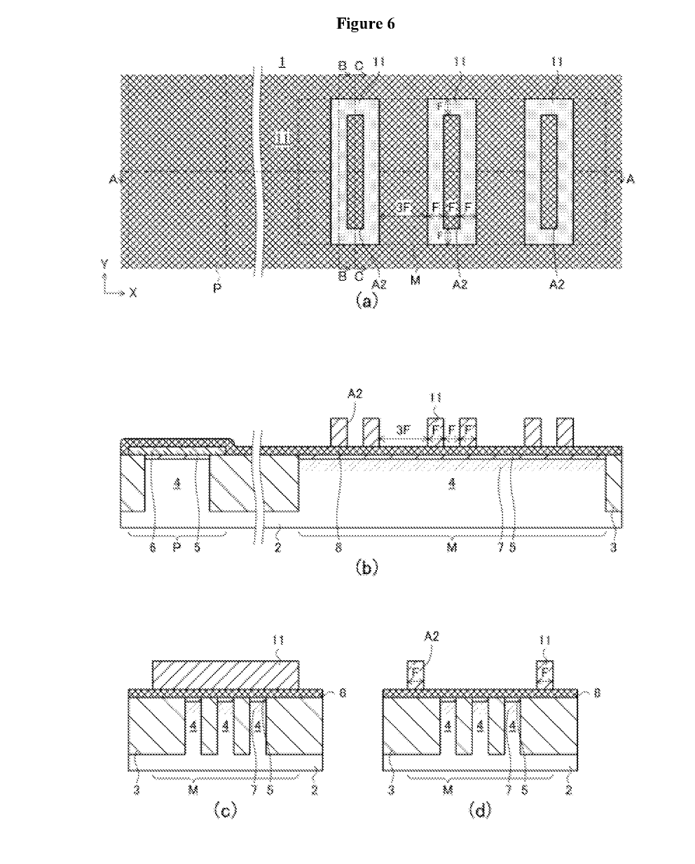

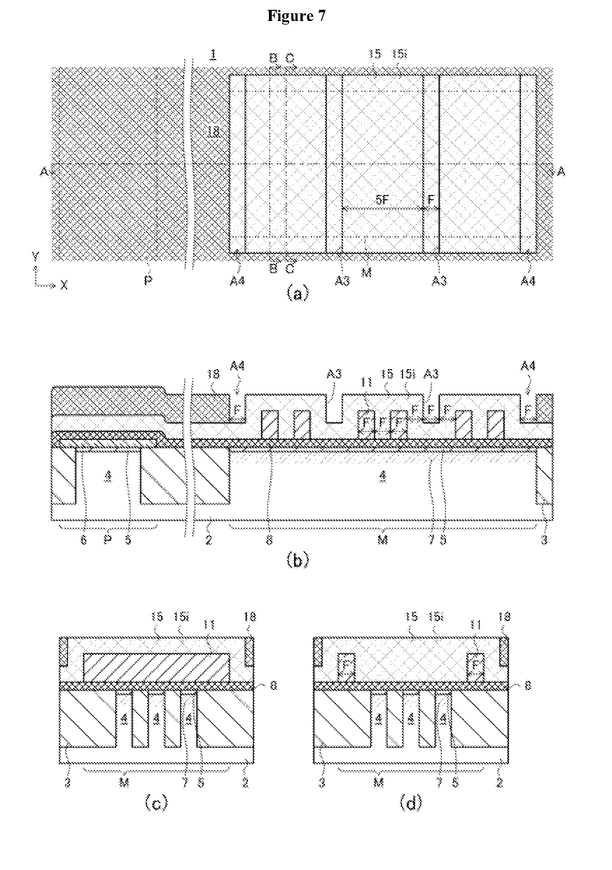

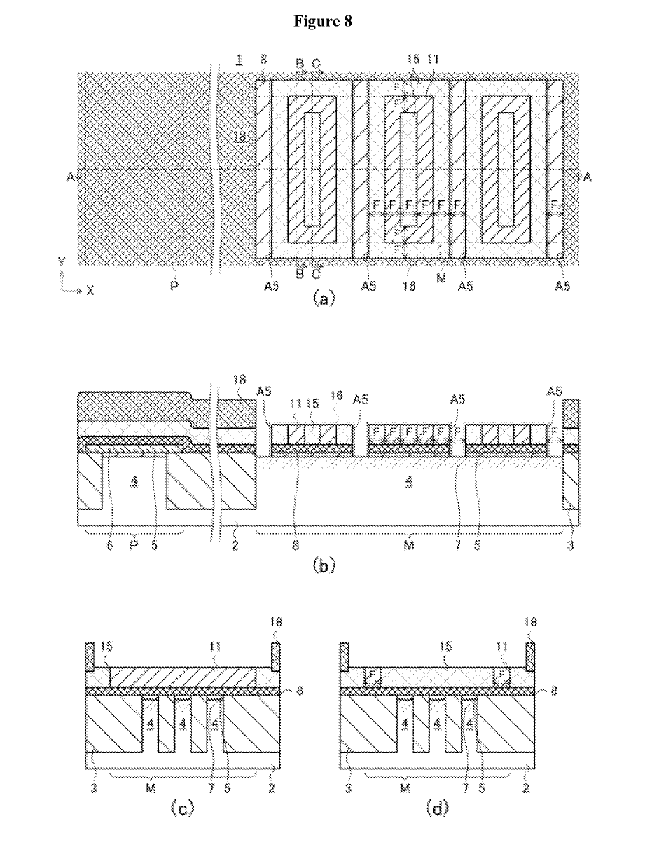

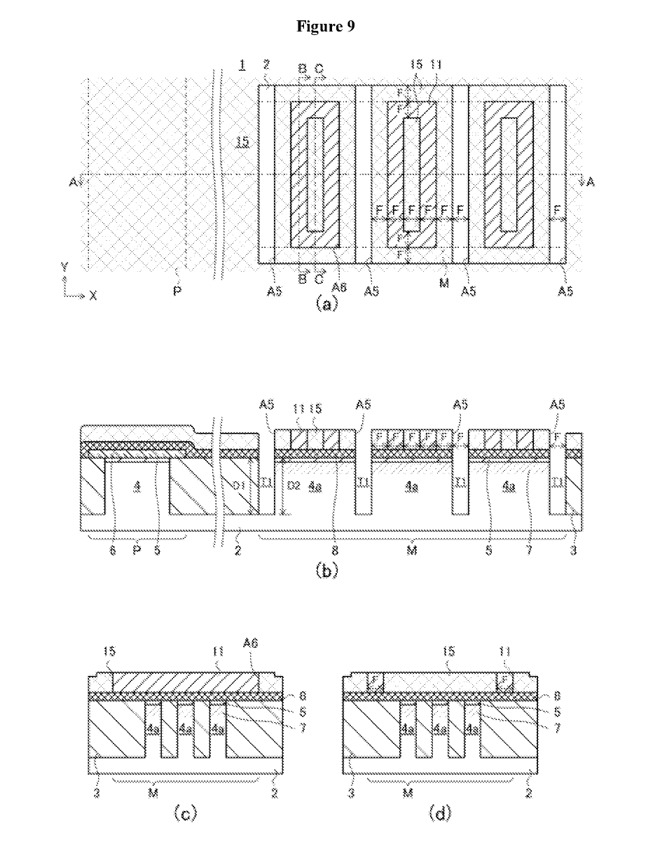

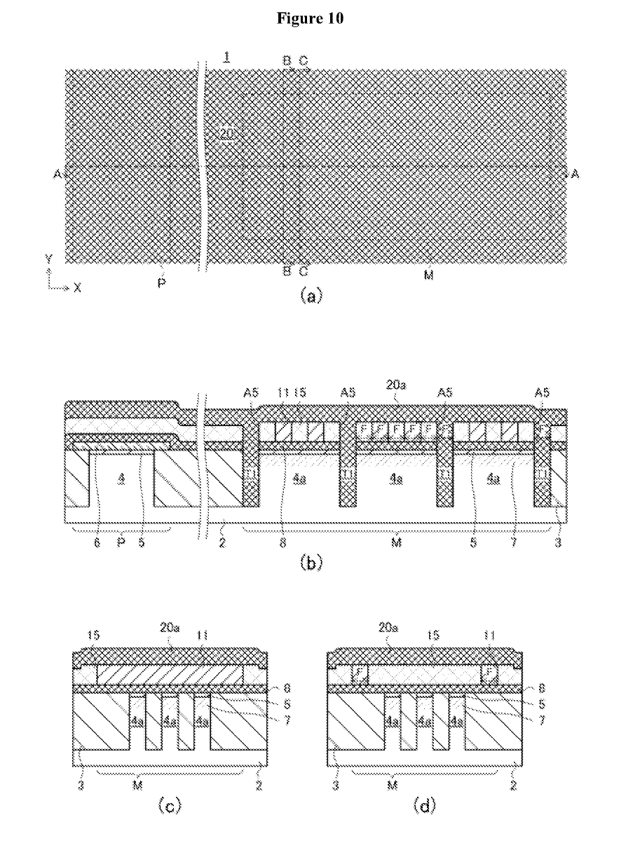

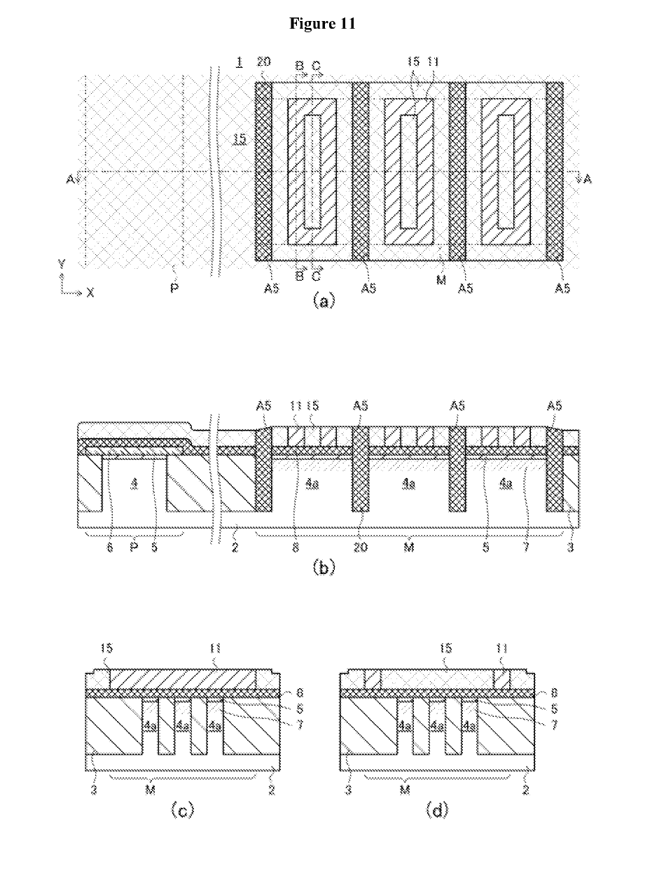

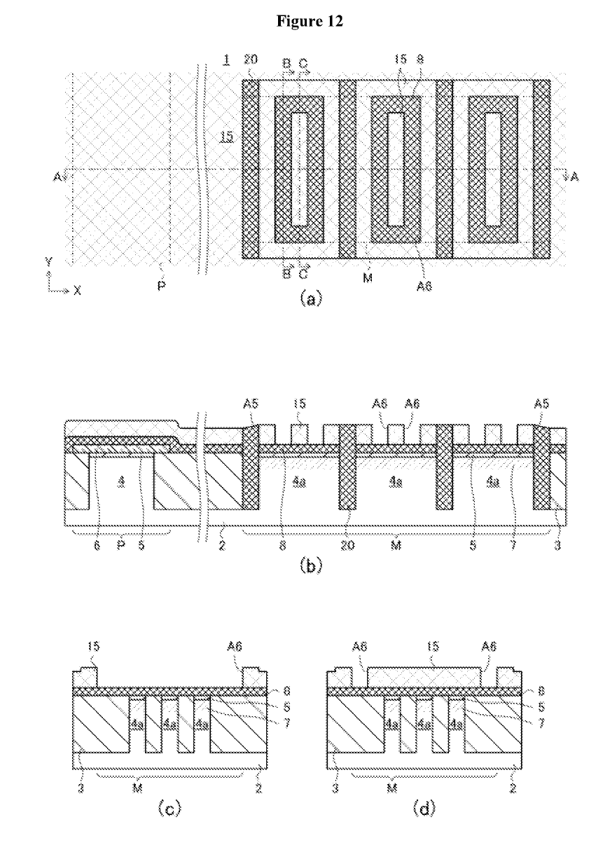

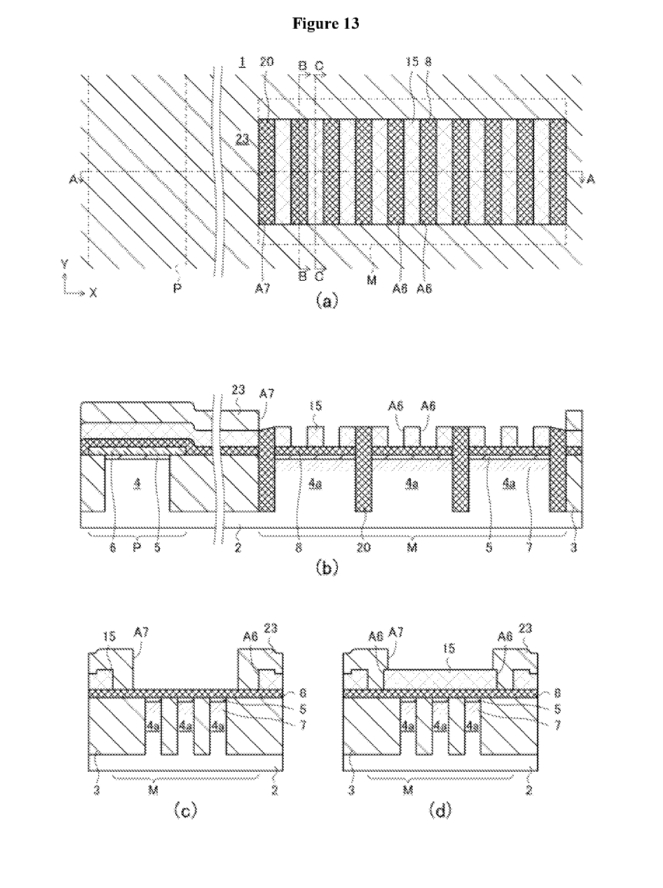

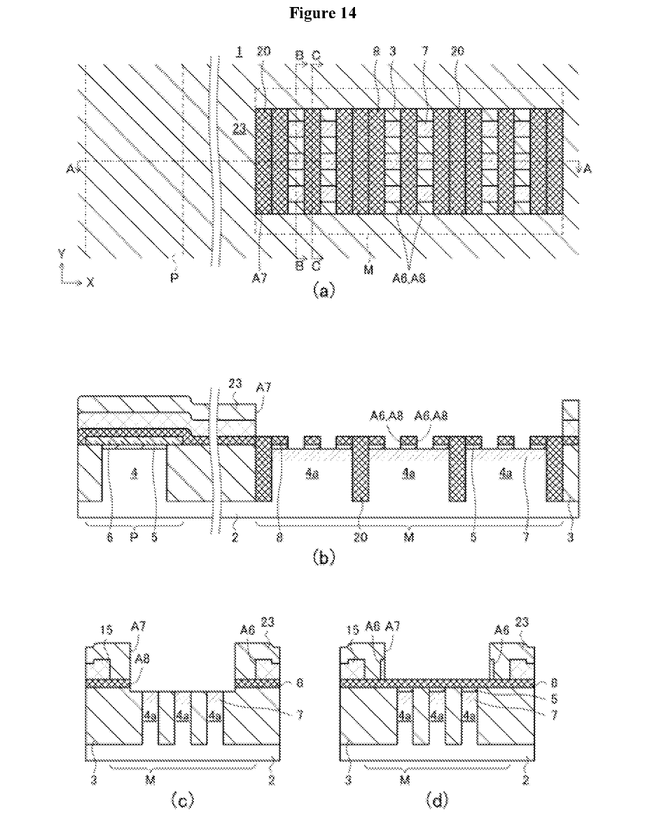

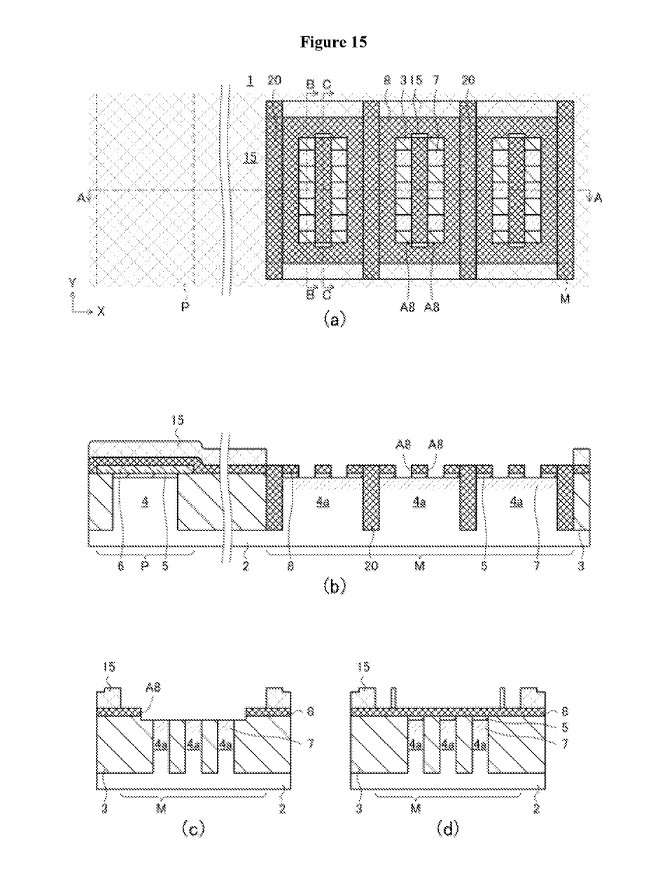

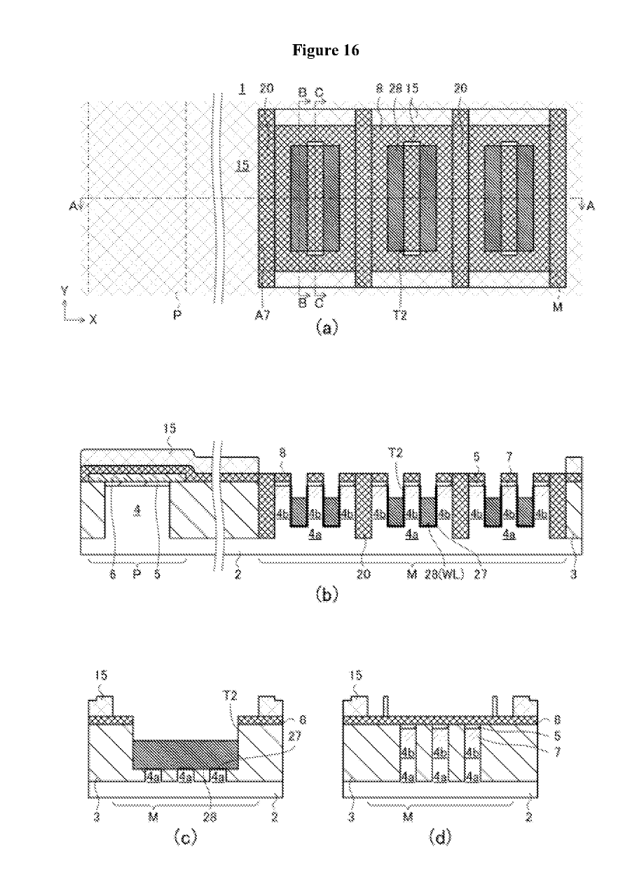

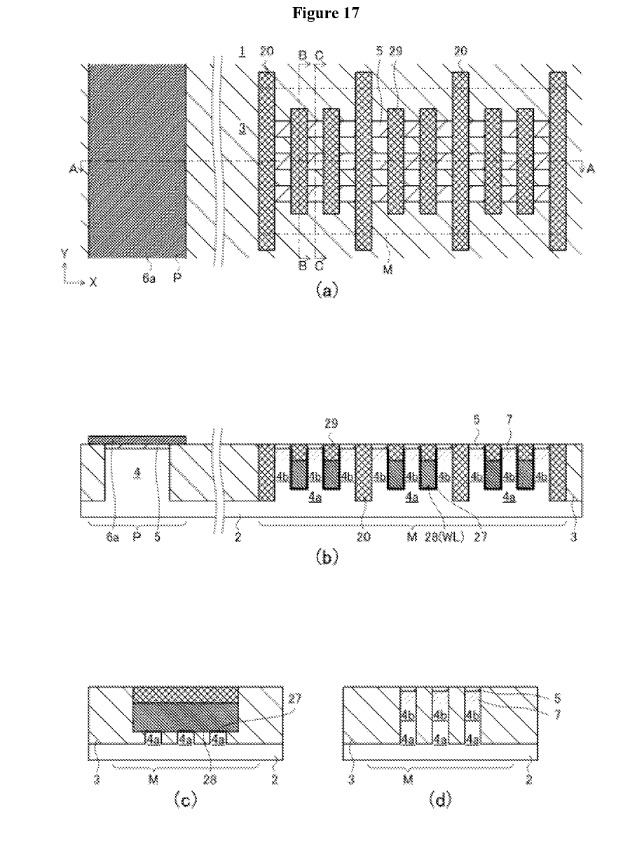

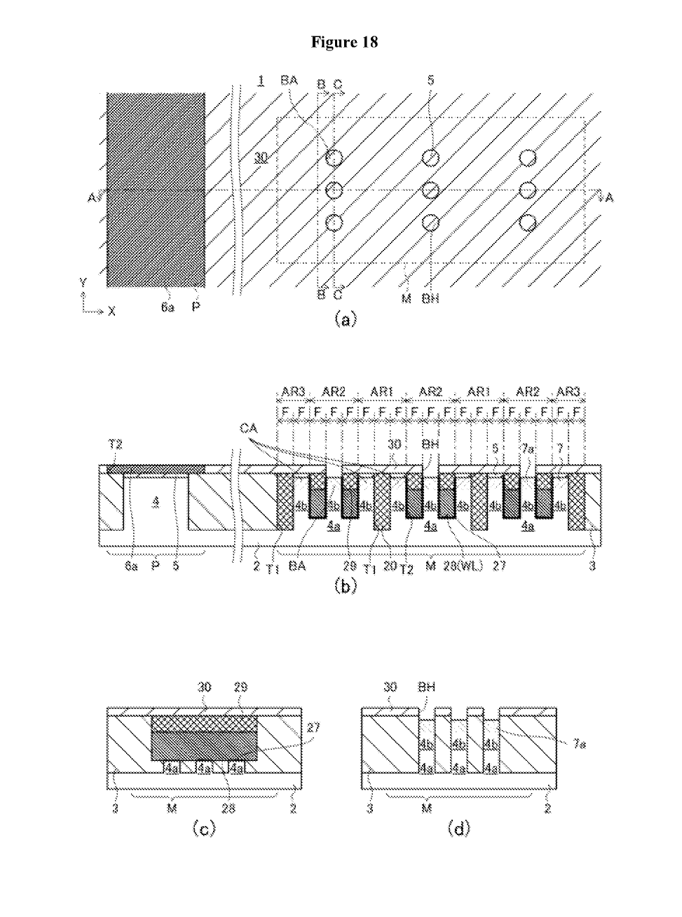

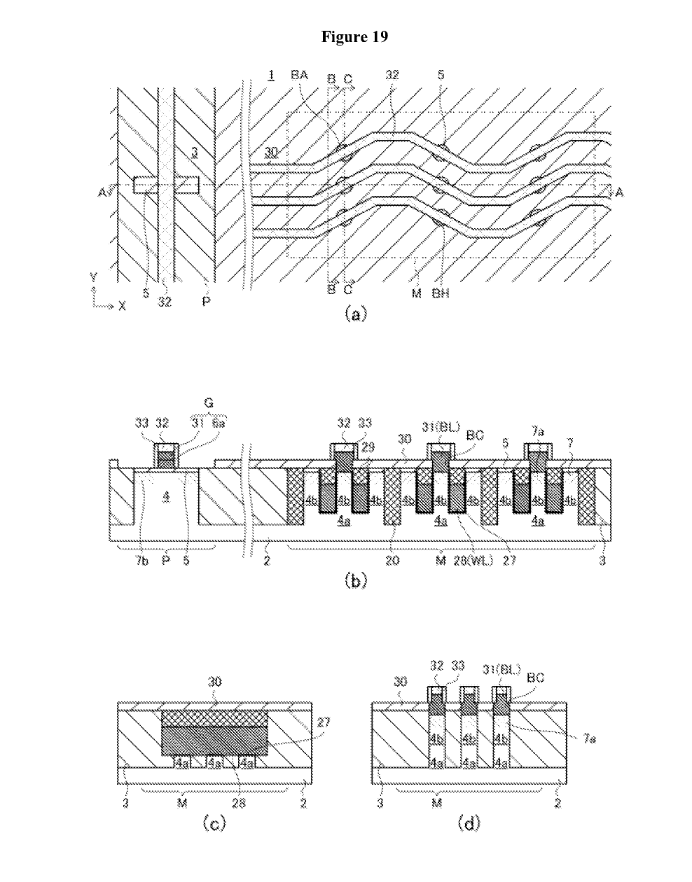

### BRIEF EXPLANATION OF THE DRAWINGS

[FIG. 1](a) is a plan view of a semiconductor device 1 manufactured in accordance with a method of manufacturing a semiconductor device according to a preferred mode of embodiment of the present invention. (b), (c) and (d) are respectively cross-sectional views of the semiconductor device 1 corresponding to the line A-A, the line B-B and the line C-C in (a).

[FIG. 2](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 3](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 4](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 5](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 6](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 7](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 8](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 9](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 10](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 11](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 12](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 13](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 14](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 15](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 16](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 17](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 18](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

[FIG. 19](a) is a plan view of the semiconductor device 1 illustrated in FIG. 1(a), during the manufacturing process. (b), (c) and (d) are respectively cross-sectional views of the semiconductor device 1 corresponding to the line A-A, the line B-B and the line C-C in (a).

### MODES OF EMBODYING THE INVENTION

Preferred modes of embodiment of the present invention will now be described in detail with reference to the accompanying drawings. The structure of a semiconductor device 1 manufactured in accordance with a method of manufacturing a semiconductor device according to this mode of embodiment will first be described in outline, and then the method of manufacturing the semiconductor device 1 will be described in detail.

The structure of the semiconductor device 1 will first be described with reference to FIG. 1(a) to (d). The semiconductor device 1 is a DRAM comprising a semiconductor substrate 2 (silicon substrate), as illustrated in FIG. 1(b) to (d). As illustrated in FIG. 1(a), a memory cell region M and a peripheral circuit region P are provided on the main surface of the semiconductor substrate 2.

In the memory cell region M, rectangular active regions K2 (second active regions) that are elongated in the X-direction (word line direction; first direction) illustrated in the drawings, are disposed in a repeating manner in both the X-direction and the Y-direction (a direction which intersects the X-direction in the plane of the main surface of the semiconductor substrate 2; in other words, a direction perpendicular to the X-direction in the plane of the main surface of the semiconductor substrate 2; bit line direction; second direction). In other words, the plurality of active regions K2 are disposed in a matrix formation. It should be noted that only nine active regions K2 are illustrated in FIG. 1(a), but this is in order to facilitate understanding of the drawing and to simplify the description, and in practice multiple active regions K2 are disposed.

Each active region K2 is demarcated by means of element isolation regions 20 (first element isolation regions) extending in the Y-direction and element isolation regions 3 (second element isolation regions) extending in the X-direction. The element isolation regions 20 and 3 are both formed from insulating films. More specifically, the element isolation regions 20 are formed from silicon nitride films, and the element isolation regions 3 are formed from silicon dioxide films. As illustrated in FIG. 1(a), for example, the element isolation regions 3 are also embedded in regions other than the memory cell region M.

A plurality of word lines WL, each extending in the X-direction, and a plurality of bit lines BL, each extending in the Y-direction, are disposed in the memory cell region M. Each word line WL is disposed in such a way as to pass through a series of active regions K2 aligned side-by-side in the Y-direction, with two word lines WL corresponding to one active region K2. Two cell transistors are disposed in each active region K2, and the two word lines WL corresponding to each active region K2 form the gate electrodes of the cell transistors. Each word line WL is an embedded word line formed by means of a conductive film which is embedded in the main surface of the semiconductor substrate 2, and a gate insulating film 27 is disposed between each word line WL and the semiconductor substrate 2.

In each active region K2, the region located between the two corresponding word lines WL (the central part in the X-direction) is a bit line contact region BA. In the semiconductor device 1, one bit line BL is provided for each series of active regions K2 aligned in the X-direction. Each bit line BL is disposed in such a way as to pass through the bit line contact regions BA in each of the corresponding plurality of active regions K2. Further, as illustrated in FIG. 1(a), each bit line BL is formed in a serpentine manner in order to avoid capacitor contact plugs CC discussed hereinafter. Each bit line BL is connected to the bit line contact regions BA in the corresponding active region K2 by way of bit line contact plugs BC.

In each active region K2, the regions located to the outside of the two corresponding word lines WL (both ends in the X-direction) are capacitor contact regions CA. In the semiconductor device 1, a cell capacitor C is disposed above each capacitor contact region CA. As illustrated in FIG. 1(b), each cell capacitor C comprises one lower electrode 38 for each cell capacitor C, and a capacitative insulating film 39 and an upper electrode 40 which are common to the cell capacitors C. The lower electrode 38 of each cell capacitor C is connected to the corresponding capacitor contact region CA by way of the capacitor contact plug CC provided therebelow.

An impurity-diffused region 7 is provided in a part of the main surface of the semiconductor substrate 2 corresponding to the capacitor contact region CA, and an impurity-diffused region 7a is provided in a part of the main surface of the semiconductor substrate 2 corresponding to the bit line contact region BA. The impurity-diffused regions 7 and 7a respectively form one and the other of the drain and the source of the corresponding cell transistor.

The operation of the cell transistors will now be described. When a certain word line WL is activated, a channel is generated between the impurity-diffused region 7 and the impurity-diffused region 7a in the cell transistor corresponding to said word line WL. The cell transistor thus turns on, and the corresponding bit line BL and the lower electrode 38 of the corresponding cell transistor C conduct. Meanwhile, if the certain word line WL becomes inactive, the channel between the impurity-diffused region 7 and the impurity-diffused region 7a in the cell transistor corresponding to said word line WL ceases to exist. The cell transistor thus turns off, and the corresponding bit line BL and the lower electrode 38 of the corresponding cell transistor C are electrically isolated.

As illustrated in FIG. 1(a), an active region KP is disposed in the peripheral circuit region P. It should be noted that only one active region KP is illustrated in FIG. 1(a), but this is in order to facilitate understanding of the drawing and to simplify the description, and in practice multiple active regions KP are disposed. Further, the active region KP illustrated in FIG. 1(a) is in the shape of a rectangle that is elongated in the X-direction, but the shape of the actual active region KP is not limited to this. The following description assumes that the active region KP is in the shape of a rectangle that is elongated in the X-direction.

One planar transistor (peripheral circuit transistor) is formed in the active region KP illustrated in FIG. 1(a). A central portion, in the X-direction, of the active region KP is covered by a gate wiring line G, with the interposition of an insulating film 5 (gate insulating film). Further, impurity-diffused regions 7b are formed in both end portions, in the X-direction, of the active region KP. Of these, the impurity-diffused region 7b corresponding to one end portion, in the X-direction, of the active region KP is connected to a drain wiring line D in an upper layer by way of a drain contact plug DC. Meanwhile, the impurity-diffused region 7b corresponding to the other end portion, in the X-direction, of the active region KP is connected to a source wiring line S in an upper layer by way of a source contact plug SC. It should be noted that in FIG. 1(b) the drain wiring line D and the source wiring line S are formed in the same layer as the cell capacitors C, but the location in which these are formed in practice is not limited to this.

The operation of the peripheral circuit transistor will now be described. When the gate wiring line G is activated, a channel is generated between the corresponding two impurity-diffused regions 7b. The peripheral circuit transistor thus turns on, and the corresponding drain wiring line D and the corresponding source wiring line S conduct. Meanwhile, if the gate wiring line G becomes inactive, the channel between the corresponding two impurity-diffused regions 7b ceases to exist. The peripheral circuit transistor thus turns off, and the corresponding drain wiring line D and the corresponding source wiring line S are electrically isolated.

The structure of the semiconductor device 1 has been described in outline hereinabove. A method of manufacturing the semiconductor device 1 will now be described in detail with reference to FIG. 2 to FIG. 19.

First, as illustrated in FIG. 2(a) to (d), element isolation regions 3 (second element isolation regions) are embedded into the main surface of a semiconductor substrate 2 comprising a p-type silicon single crystal, to form a plurality of silicon pillars 4, each extending in the X-direction, in the memory cell region M, and also to form a silicon pillar 4 in the peripheral circuit region P. The silicon pillars 4 in the memory cell region M form a plurality of active regions K1 (first active regions) which extend in the X-direction and are disposed in a repeating manner in the Y-direction. Element isolation regions 20 are formed in a later step to divide each of the active regions K1 into a plurality of the active regions K2 discussed hereinabove. The silicon pillar 4 in the peripheral circuit region P forms the active region KP discussed hereinabove. It should be noted that in the memory cell region M, the width of the silicon pillars 4 (active regions K1) in the Y-direction and their spacing in the Y-direction are preferably equal to the minimum processing dimension F (=30 nm) defined by the limit of resolution for lithography, as illustrated in FIG. 2(a).

More specifically, the element isolation regions 3 are preferably formed as follows. To elaborate, first a pad silicon dioxide film (which is not shown in the drawings) having a thickness of 2 nm and a silicon nitride film (which is not shown in the drawings) having a thickness of 100 nm are deposited successively onto the main surface of the semiconductor substrate 2. Lithography and dry etching are then used to pattern the silicon nitride film into the pattern of the silicon pillars 4 and to etch the main surface of the semiconductor substrate 2, using the patterned silicon nitride film as a mask. In this way, trenches are formed in the main surface of the semiconductor substrate 2, and a silicon dioxide film (fifth insulating film), which is the material from which the element isolation regions 3 are formed, is then deposited to a thickness that fills the interiors of the trenches. The silicon dioxide film and the silicon dioxide film are then removed by CMP (Chemical Mechanical Polishing) until the main surface of the semiconductor substrate 2 is exposed. The state illustrated in FIG. 2(a) to (d) is obtained by means of the steps described hereinabove. It should be noted that the height D1 of the element isolation regions 3 is preferably 250 nm.

As illustrated in FIG. 3(a) to (d), a silicon dioxide film 5 is next formed on the exposed surface of the semiconductor substrate 2 by thermal oxidation. The silicon dioxide film 5 is formed as a pad oxide film for protecting the semiconductor substrate 2. However, the silicon dioxide film 5 formed in the active region KP is also used as a gate insulating film of a peripheral circuit transistor.

After the silicon dioxide film 5 has been formed, an impurity-doped amorphous silicon film 6 having a thickness of 10 nm is deposited over the entire surface, and the parts thereof that are formed in regions other than the peripheral circuit region P are removed. This removal is preferably performed by forming a mask pattern (which is not shown in the drawings) covering the peripheral circuit region P, and etching the impurity-doped amorphous silicon film 6 using the mask pattern as a mask. The impurity-doped amorphous silicon film 6 formed here is an insulating film, but it is modified to become a conductive film during the course of the subsequent steps, to form part of the gate wiring line G illustrated in FIG. 1(b), for example. After the impurity-doped amorphous silicon film 6 in regions other than the peripheral circuit region P has been removed, impurity-diffused regions 7 are formed in the upper portions of the active regions K1.

As illustrated in FIG. 4(a) to (d), a hardmask film 8, which is a silicon nitride film having a thickness of 40 nm, is deposited over the entire surface by CVD (Chemical Vapor Deposition), and an antireflective film 9a having a thickness of 200 nm and a silicon-containing antireflective film 9b having a thickness of 32 nm are deposited successively by spin coating. The laminated film comprising the antireflective film 9a and the silicon-containing antireflective film 9b form a sacrificial film 9. Anisotropic dry etching is then performed using a mask pattern, which is not shown in the drawings, as a mask, to process the sacrificial film 9 into a sacrificial film pattern (first sacrificial film pattern) having a plurality of opening portions A1 (first opening portions) in the memory cell region M. The upper surface of the hardmask film 8 is exposed at the bottom surface of each opening portion A1.

The opening portions A1 are each disposed in such a way as to extend over a plurality of active regions K1 (see FIG. 2(a)) which are aligned side-by-side in the Y-direction, and the opening portions A1 are disposed aligned in the X-direction. As illustrated in FIG. 4(a), the planar shape of the opening portions A1 is preferably a rectangular shape in which the size in the X-direction is three times the minimum processing dimension F (3F), and the size in the Y-direction is nine times the minimum processing dimension F (9F). It should be noted that the size in the Y-direction is determined in such a way that the end portions, in the Y-direction, of the opening portions A1 are located in positions that are 2F from the active regions K1 at the ends in the Y-direction, and the size in the Y-direction thus varies depending on the number of active regions K1. Further, the spacing, in the X-direction, between the opening portions A1 is preferably three times the minimum processing dimension F (3F), as illustrated in FIG. 4(a).

As illustrated in FIG. 5(a) to (d), a sacrificial film 11 comprising a silicon dioxide film (third insulating film) is then deposited over the entire surface. As illustrated in FIGS. 5(b) and (d), the deposition quantity of the sacrificial film 11 at this time is set in such a way that the thickness in the lateral direction of the parts which form side-wall insulating films covering the inner walls of the opening portions A1 is equal to the minimum processing dimension F. Further, because the sacrificial film 9 formed from the antireflective film, which is an organic substance, has poor heat resistance, MLD (Molecule Layer Deposition), with which deposition can be performed at low temperatures of 100° C. or less, is used to deposit the sacrificial film 11.

Deposition by MLD is preferably carried out by repeatedly executing the following steps while the semiconductor substrate 2 is maintained at a temperature of 50° C., for example, namely: a first step in which an aminosilane, which is a silicon feedstock, is introduced into a deposition chamber and is caused to be adsorbed onto the semiconductor substrate 2; a second step in which the residual aminosilane in the deposition chamber is vented; a third step in which an oxidant such as ozone is introduced in order to oxidize the adsorbed aminosilane; and a fourth step in which the introduced oxidant is vented. The sacrificial film 11 formed in this way is a laminated film in which thin films at the molecular level are laminated together. It should be noted that MLD has the advantage that damage to the sacrificial film 9 is suppressed because deposition can be performed at a low temperature, in addition to which it also has the advantage that step coverage is excellent, because MLD employs a surface adsorption reaction.

The sacrificial film 11 is then etched back by anisotropic etch-back using a fluorine-containing plasma, to process the sacrificial film 11 into the shape of side-wall insulating films (first side-wall insulating films) covering the side surfaces (inner surfaces) of the opening portions A1. This etching back is performed until the sacrificial film 9 or the hardmask film 8 are exposed. As illustrated in FIG. 6(a) to (d), the sacrificial film 9 is then selectively removed by dry etching using an oxygen-containing plasma. In this way, a plurality of closed-loop patterns, each comprising the sacrificial film 11, are formed in the memory cell region M, as illustrated in FIG. 6(a). The closed-loop patterns (sacrificial films 11) formed in this way have a shape which follows the inner peripheries of the opening portions A1 illustrated in FIG. 4(a). The width, in the lateral direction, of each closed-loop pattern (sacrificial film 11) is the minimum processing dimension F, as illustrated in FIG. 6(a), (b) (d). Further, the width (the width in the X-direction) of the opening portion A2 formed in the center of each closed-loop pattern (sacrificial film 11) is equal to the minimum processing dimension F.

As illustrated in FIG. 7(a) to (d), a sacrificial film 15 comprising a silicon nitride film (fourth insulating film) is then deposited over the entire surface. As illustrated in FIGS. 7(b) and (d), the deposition quantity of the sacrificial film 15 at this time is set in such a way that the thickness in the lateral direction of the parts which form side-wall insulating films covering the outer peripheral walls of the closed-loop patterns (sacrificial films 11) is equal to the minimum processing dimension F. In this way the opening portions A2 are filled by the sacrificial film 15.

As illustrated in FIG. 7(a) to (d), the sacrificial film 15 has parts (island patterns 15i) which are raised up in the form of islands, in locations corresponding to each of the plurality of opening portions A1 illustrated in FIG. 4(a), for example. More specifically, each island pattern 15i has a shape, as seen in a plan view, which is wider than the corresponding opening portion A1 by the minimum processing dimension F in each of the four lateral directions. Recessed portions A3 having a width in the X-direction equal to the minimum processing dimension F are formed in the regions between the island patterns 15i. Further, the regions extending from each of the two island patterns 15i located at the two ends in the X-direction, to a location separated therefrom by the minimum processing dimension in the X-direction are referred to in the following description as regions A4, as illustrated in FIG. 7(b).

After the sacrificial film 15 has been deposited, a photoresist 18 is applied over the entire surface. A part of the photoresist 18 is then removed by lithography to expose the island patterns 15i, the recessed portions A3 and the regions A4, as illustrated in FIG. 7(a) to (d).

The sacrificial film 15 is then etched back by anisotropic etch-back, using the photoresist 18 (first mask pattern) as a mask. More specifically, the sacrificial film 15 is preferably etched back using a gas plasma containing trifluoromethane (CHF₃) gas or difluoromethane (CH₂F₂), under conditions in which the pressure is 7 Pa, the high-frequency power is 500 W and the bias power is 100 W. When the hardmask film 8 has been exposed as a result of this etching back, the conditions are modified in such a way that the silicon nitride film and the silicon dioxide film are etched at the same rate, and etching continues until the upper surfaces of the silicon pillars 4 are exposed. In this way, the upper surfaces of each of the sacrificial films 11 and 15 become coplanar, as illustrated in FIG. 8(a) to (d). Further, the sacrificial films 15 are processed into the shape of side-wall insulating films (second side-wall insulating films) covering the side surfaces of the sacrificial films 11.

By means of the steps up to this point, island patterns 16 are formed on the main surface of the semiconductor substrate 2 for each of the opening portions A1 illustrated in FIG. 4(a), for example, as illustrated in FIG. 8(a) to (d). Each island pattern 16 is formed from the hardmask film 8, and the sacrificial films 11 and 15, formed on the upper surface of said hardmask film 8. Opening portions AS (second opening portions) having a width in the X-direction equal to the minimum processing dimension F, and a width in the Y-direction equal to that of the island patterns 16, are formed between each two adjacent island patterns 16, and between the island patterns 16 located at the two ends in the X-direction, and the photoresist 18. These island patterns 16 and opening portions AS form a second sacrificial film pattern.

As will be apparent from the description up to this point, the opening portions AS are formed in self-alignment relative to the opening portions A1. Therefore in this method of manufacture the locations in which the opening portions AS are formed can be matched accurately to the locations in which the opening portions AS are formed.

When formation of the island patterns 16 has been completed, the photoresist 18 is removed. As a result, the sacrificial film 15 is exposed in the regions in which the photoresist 18 was formed. The silicon pillars 4 are then selectively etched by anisotropic dry etching, using the second sacrificial film pattern (the sacrificial films 11 and 15 and the hardmask film 8) as a mask. More specifically, the silicon pillars 4 are preferably etched using a mixed-gas plasma containing hydrogen bromide (HBr), chlorine (Cl₂) and oxygen (O₂), under conditions in which the pressure is 0.5 Pa, the high-frequency power is 500 W and the bias power is 150 W.

By means of the steps up to this point, first trenches T1 are formed vertically below the opening portions A5, as illustrated in FIG. 9(a) to (d). It should be noted that the depth D2 of the first trenches T1 from the surface of the semiconductor substrate 2 is preferably set to be the same as the height D1 of the element isolation regions 3, namely 250 nm. The plurality of first trenches T1 formed in this way each extend in the Y-direction, and they divide the silicon pillars 4 (active regions K1) in the memory cell region M in the X-direction. Further, each first trench T1, other than those located at the two ends, is located centrally in the X-direction between adjacent opening portions A1 (FIG. 4). Each part of the divided silicon pillars 4 forms a silicon pillar 4a, and these form the active regions K2 illustrated in FIG. 1(a) to (d).

After the first trenches T1 have been formed, a silicon nitride film 20a (first insulating film) is deposited over the entire surface by CVD, as illustrated in FIG. 10(a) to (d). The thickness of the silicon nitride film 20a deposited here is a thickness at least sufficient to fill the first trenches T1. The deposited silicon nitride film 20a is then etched back to expose the upper surfaces of the sacrificial films 11 and 15, as illustrated in FIG. 11(a) to (d). In this way, element isolation regions 20 (see FIG. 1) extending in the Y-direction are formed.

The sacrificial films 11, which are silicon dioxide films, are then selectively removed by etching, using the silicon nitride films as a mask. This etching is preferably performed using a hydrofluoric acid (HF)-containing solution. A plurality of closed-loop opening patterns A6, at the bottom surface of each of which the upper surface of the hardmask film 8 is exposed, are formed in this way, as illustrated in FIG. 12(a) to (d).

A mask pattern 23 (second mask pattern) covering the parts of the plurality of closed-loop opening patterns A6 that extend in the X-direction (the parts at the two ends in the Y-direction) is then formed by lithography, as illustrated in FIG. 13(a) to (d). The mask pattern 23 is formed in such a way as also to cover the regions other than the memory cell region M. The silicon nitride films and the silicon dioxide films are then removed by anisotropic dry etching, using the mask pattern 23 as a mask, until the upper surfaces of the silicon pillars 4a are exposed, as illustrated in FIG. 14(a) to (d). By means of this process, opening portions A8 (third opening portions) are formed in the parts of each of the plurality of closed-loop opening patterns A6 that are not covered by the mask pattern 23. The silicon pillars 4a and the element isolation regions 3 are exposed at the bottom surfaces of the open portions A8. The parts of the sacrificial films 15 that were formed in the opening portion of the mask pattern 23 (the opening portion A7 illustrated in the drawings) are eliminated, and the hardmask film 8 is exposed in the regions in which the eliminated sacrificial films 15 were formed.

As will be apparent from the description up to this point, the opening portions A8 are also formed in self-alignment relative to the opening portions A1. Therefore in this method of manufacture the locations in which the opening portions A8 are formed can also be matched accurately to the locations in which the opening portions AS are formed.

The mask pattern 23 is then removed, as illustrated in FIG. 15(a) to (d). The bottom surfaces of the opening portions A8 are then etched by anisotropic dry etching, using the silicon nitride films as a mask. As discussed hereinabove, the silicon pillars 4a and the element isolation regions 3 are exposed at the bottom surfaces of the open portions A8, and therefore this etching is performed in two stages. More specifically, the element isolation regions 3 comprising the silicon dioxide film are first selectively etched, after which the silicon pillars 4a comprising silicon are selectively etched. In this way, second trenches T2 are formed vertically below the opening portions A8, as illustrated in FIG. 16(a) to (d). The second trenches T2 formed in this way extend in the Y-direction in locations whereby the second trenches make internal contact with the two surfaces of each of the opening portions A1, illustrated in FIG. 4(a), for example, that oppose one another in the X-direction. By forming the second trenches T2, each of the plurality of silicon pillars 4a is divided into three silicon pillars 4b.

Gate insulating films 27 (second insulating films) covering the inner surfaces of the second trenches T2 are then formed by thermal oxidation, and then word lines WL are formed by embedding conductive films 28 into the second trenches T2, as illustrated in FIG. 16(a) to (d). As a specific method of forming the conductive films 28, a method is preferably employed in which a metal film containing tungsten is deposited over the entire surface by CVD, after which this film is etched back. The amount of etch-back carried out at this time is preferably adjusted in such a way that the upper surfaces of the word lines WL are at approximately the same level as the lower surfaces of the impurity-diffused regions 7.

A silicon nitride film is then deposited to a thickness that fills the remainder of the second trenches T2. This silicon nitride film is integrated with the silicon nitride film which forms each of the sacrificial films 15, the hardmask films 8, and the element isolation regions 20. The silicon nitride film that is integrated in this way is then etched back until the surface of the silicon nitride film 5 is exposed. In this way, cap insulating films 29 having upper surfaces at the same height as the upper surfaces of the silicon dioxide films 5 are formed in the upper portions of the second trenches T2, as illustrated in FIG. 17(a) to (d).

It should be noted that the impurity-doped amorphous silicon film 6 that is exposed as a result of etching back the silicon nitride film, as illustrated in FIG. 17(a) and (b), has, by means of the steps up to this point, been converted into a polycrystalline silicon film 6a, which is an electrical conductor. In the drawings, this film is shown as the polycrystalline silicon film 6a from the step illustrated in FIGS. 17(a) and (b), but in practice the impurity-doped amorphous silicon film 6 is gradually converted into the polycrystalline silicon film 6a through several heat treatment steps that are carried out during the process up to this point.

A silicon dioxide film is then formed over the entire surface, and this is etched by CMP until the upper surface of the polycrystalline silicon film 6a is exposed. In this way, an interlayer insulating film 30 covering the regions other than the peripheral circuit region P is formed, as illustrated in FIG. 18(a) to (d).

A plurality of bit line contact holes BH, illustrated in FIGS. 18(a), (b) and (d), are then formed in the interlayer insulating film 30 by selectively etching the silicon dioxide film. The planar locations of these bit line contact holes BH are locations that, when seen in a plan view, overlap the bit line contact regions BA (the central parts of the active regions K2 in the X-direction), also illustrated in FIG. 1(a). Therefore the upper surfaces of the silicon pillars 4b corresponding to the bit line contact regions BA are exposed at the bottom surfaces of the bit line contact holes BH.

When the bit line contact holes BH have been formed, an n-type impurity such as arsenic is ion-implanted into the bottom surfaces thereof. In this way, the parts of the impurity-diffused regions 7 in which implantation has occurred are changed into high-concentration impurity-diffused regions 7a. A metal film 31 containing tungsten, and a cover insulating film 32 comprising a silicon nitride film, are then successively deposited and are patterned by photolithography and dry etching as illustrated in FIG. 19(a) to (d). In this patterning, the polycrystalline silicon film 6a in the peripheral circuit region P is also patterned at the same time. The metal film 31 after patterning forms bit lines BL in the memory cell region M, and together with the polycrystalline silicon film 6a forms a gate wiring line G in the peripheral circuit region P. After the patterning has been completed, side-wall insulating films 33 covering the sidewalls of the pattern are formed. Further, an n-type impurity such as arsenic is ion-implanted into the upper surface of the silicon pillar 4 in the peripheral circuit region P by way of the exposed silicon dioxide film 5. In this way, impurity-diffused regions 7b are formed at both sides, in the X-direction, of the gate wiring line G, as seen in a plan view.

A silicon dioxide film is then formed over the entire surface, and this is etched by CMP until the upper surface of the cover insulating film 32 is exposed. In this way, an interlayer insulating film 35 filling the spaces between the bit lines BL and the gate wiring lines G is formed, as illustrated in FIG. 1(a) to (d). Capacitor contact plugs CC are then formed in the memory cell region M, penetrating through the interlayer insulating films 35 and 30 in locations overlapping, as seen in a plan view, the capacitor contact regions CA (both end portions of the active regions K2 in the X-direction) illustrated in FIG. 1(a), and a drain contact plug DC and a source contact plug SC are formed in the peripheral circuit region P, each penetrating through the interlayer insulating films 35 and 30 in locations overlapping, as seen in a plan view, the impurity-diffused regions 7b. Further, cell capacitors C (memory cell region M), a drain wiring line D and a source wiring line S (peripheral circuit region P), and interlayer insulating films 37 and 41 and the like are formed on the upper surface of the interlayer insulating film 35, thereby completing the semiconductor device 1.

Here, referring again to FIG. 18(b), the positional relationships in the X-direction between the first and second trenches T1 and T2, the bit line contact region BA, and the capacitor contact region CA will be described collectively in more detail

Regions AR1 to AR3 illustrated in FIG. 18(b) are regions that are defined in relation to the opening portions A1 illustrated in FIG. 4(b), for example More specifically, the regions AR2 (second regions) are regions within the main surface of the semiconductor substrate 2 that overlap the opening portions A1 as seen in a plan view. Meanwhile, the regions AR1 (first regions) are regions within the main surface of the semiconductor substrate 2 located between opening portions A1 that are adjacent to one another in the X-direction as seen in a plan view. Further, the regions AR3 are regions within the main surface of the semiconductor substrate 2 located between the regions AR2 located at the ends in the X-direction, and the element isolation regions 3.

The first trenches T1, having a width in the X-direction equal to F, are formed in the centers, in the X-direction, of the regions AR1. Both ends, in the X-direction, of the regions AR1 (the two regions located between the first trenches T1 and the regions AR2 as seen in a plan view) are the capacitor contact regions CA, and the width in the X-direction of the capacitor contact regions CA is F. Therefore the width, in the X-direction, of the regions AR1 is 3F, comprising the sum of the width F, in the X-direction, of the first trench T1, and 2F, which is twice the width F, in the X-direction, of the capacitor contact region CA.

The regions AR2 are formed from two second trenches T2 and the bit line contact region BA located between said two trenches T2. The widths, in the X-direction, of the second trenches T2 and the bit line contact region BA are each F. Therefore the width, in the X-direction, of the regions AR2 is 3F, comprising the sum of 2F, which is twice the width F, in the X-direction, of the second trench T2, and the width F, in the X-direction, of the bit line contact region BA. It should be noted that the width, in the X-direction, of the region AR2 may be less than 3F, and in this case the width, in the X-direction, of the bit line contact region BA is preferably made to be less than F, while the widths, in the X-direction, of the second trenches T2 are maintained at F.

The regions AR3 are formed from the first trench T1 adjacent to the element isolation region 3, and the capacitor contact region CA located between said first trench T1 and the adjacent region AR2. The widths, in the X-direction, of the first trench T1 and the capacitor contact region CA are each F. Therefore the width, in the X-direction, of the regions AR3 is 2F, comprising the sum of the width F, in the X-direction, of the first trench T1, and the width F, in the X-direction, of the bit line contact region BA.

The location within the region AR2 in which the second trench T2 is formed is determined according to the location in which the sacrificial film 11, illustrated in FIG. 6(b) for example, is formed. The sacrificial films 11 are formed as side-wall insulating films on the side surfaces of the opening portions A1 illustrated in FIG. 4(b), for example, and it can thus be said that the locations in which the second trenches T2 are formed are determined according to the locations of the opening portions A1. Further, the location within the region AR1 in which the first trench T2 is formed is determined according to the location in which the island pattern 16, illustrated in FIG. 8(b) for example, is formed. The island patterns 16 are formed from the sacrificial films 11, and the sacrificial films 15 formed as side-wall insulating films on the side surfaces thereof, and it can thus be said that the locations in which the first trenches T1 are formed are also determined according to the locations of the opening portions A1. Therefore the element isolation regions 20 embedded in the first trenches T1, and the word lines WL embedded in the second trenches T2 satisfy the definition of self-alignment discussed hereinabove, and it can be said that they are formed in mutual self-alignment.

As described hereinabove, according to the method of manufacturing a semiconductor device in this mode of embodiment, the element isolation regions 20 can be formed from an insulating film, while the word lines WL and the element isolation regions 20 are formed in mutual self-alignment with respect to the X-direction. It is thus not necessary to apply a voltage to the element isolation regions 20, and the circuit can therefore be simplified.

Further, the intervals between the word lines WL and the element isolation regions 20 can be fixed (the word lines WL and the element isolation regions 20 can be formed in such a way that they do not deviate relative to one another), and therefore the widths, in the X-direction, of the two capacitor contact regions CA located at the both ends, in the X-direction, of the active regions K2, can also be fixed. To elaborate, if either one of the two capacitor contact regions CA is wide and the other is narrow, the contact resistance between the capacitor contact plug CC and the impurity-diffused region 7 in the narrower capacitor contact region CA increases. According to the method of manufacturing a semiconductor device in this mode of embodiment, such an increase in the contact resistance can be prevented.

Preferred modes of embodiment of the present invention have been described hereinabove, but various modifications to the present invention may be made without deviating from the gist of the present invention, without limitation to the abovementioned modes of embodiment, and it goes without saying that these are also included within the scope of the present invention.

### EXPLANATION OF THE REFERENCE NUMBERS

1 Semiconductor device

2 Semiconductor substrate

3 Element isolation region (fifth insulating film)

4, 4a, 4b Silicon pillar

5 Insulating film (silicon dioxide film)

6 Impurity-doped amorphous silicon film

6a Polycrystalline silicon film

7, 7a, 7b Impurity-diffused region

8 Hardmask film

9 Sacrificial film (first sacrificial film pattern)

9a Antireflective film

9b Silicon-containing antireflective film

11 Sacrificial film (third insulating film, first side-wall insulating film)

15 Sacrificial film (fourth insulating film, second side-wall insulating film)

15i Island pattern

16 Island pattern (second sacrificial film pattern)

18 Photoresist (first mask pattern)

20 Element isolation region

20a Silicon nitride film (first insulating film)

23 Mask pattern (second mask pattern)

27 Gate insulating film (second insulating film)

28 Conductive film

29 Cap insulating film

30, 35, 37, 41 Interlayer insulating film

31 Metal film

32 Cover insulating film

33 Side-wall insulating film

38 Lower electrode

39 Capacitative insulating film

40 Upper electrode

A1 Opening portion (first opening portion)

A2 Opening portion

A3 Recessed portion

A4 Region

A5 Opening portion (second opening portion)

A6 Closed-loop opening pattern

A7 Opening portion

A8 Opening portion (third opening portion)

AR1 First region

AR2 Second region

AR3 Region

BA Bit line contact region

BC Bit line contact plug

BH Bit line contact hole

BL Bit line

C Cell capacitor

VA Capacitor contact region

CC Capacitor contact plug

D Drain wiring line

DC Drain contact plug

G Gate wiring line

K1 First active region

K2 Second active region

KP Active region

M Memory cell region

P Peripheral circuit region

S Source wiring line

SC Source contact plug

T1 First trench

T2 Second trench

WL Word line

1. A method of manufacturing a semiconductor device, comprising:
forming a plurality of first active regions in the main surface of a semiconductor substrate, extending in a first direction in said main surface, and disposed in a repeating manner in a second direction which intersects said first direction;
forming a plurality of first trenches, each extending in the second direction and demarcating a plurality of second active regions formed by dividing each of the plurality of first active regions in the first direction;
forming first element isolation regions by embedding first insulating films into the plurality of first trenches;
forming second trenches, each extending in the second direction, after the first element isolation regions have been formed; and
forming second insulating films covering the inner surfaces of the second trenches, and forming wiring lines by embedding conductive films into the second trenches;
wherein the first and second trenches are formed in mutual self-alignment, relative to the first direction.

2. The method of claim 1, comprising forming a first sacrificial film pattern having a plurality of first opening portions extending over a plurality of the first active regions that are aligned side-by-side in the first direction, wherein the first trenches are located centrally in the first direction between adjacent first opening portions and extend in the second direction, and the second trenches extend in the second direction in locations whereby the second trenches make internal contact with the two surfaces of each of the plurality of first opening portions that oppose one another in the first direction.

3. The method of claim 1, comprising forming, in self-alignment relative to the first opening portions, a second sacrificial film pattern having second opening portions located centrally in the first direction between adjacent first opening portions, and wherein forming the first trenches comprises forming the first trenches by etching the semiconductor substrate located vertically below the second opening portions, using the second sacrificial film pattern as a mask.

4. The method of claim 3, wherein, of first regions in the main surface located between first opening portions that are adjacent to one another in the first direction as seen in a plan view, two regions located between the first trench and the first opening portion as seen in a plan view are capacitor contact regions, each of which connects to a capacitor.

5. The method of claim 4, wherein the width, in the first direction, of the first region is equal to the sum of twice the width, in the first direction, of the capacitor contact region and the width, in the first direction, of the first trench.

6. The method of claim 5, wherein the width, in the first direction, of the capacitor contact region and the width, in the first direction, of the first trench are each equal to a minimum processing dimension.

7. The method of claim 3, wherein second regions, which are regions in the main surface overlapping the first opening portions as seen in a plan view, are formed from two second trenches and a bit line contact region located between said two second trenches and connected to a bit line.

8. The method of claim 7, wherein the width, in the first direction, of the second region is equal to the sum of twice the width, in the first direction, of the second trench and the width, in the first direction, of the bit line contact region.

9. The method of claim 8, wherein the width, in the first direction, of the second region is at most equal to three times a minimum processing dimension, and the width, in the first direction, of the second trench is equal to the minimum processing dimension.

10. The method of claim 3, comprising:
after the first sacrificial film pattern has been formed, forming a third insulating film covering the main surface;
etching back the third insulating film to form, on the side surfaces of the first opening portions, first side-wall insulating films having a thickness, in the first direction, equal to the minimum processing dimension; and
removing the first sacrificial film pattern after the first side-wall insulating films have been formed;
wherein the second sacrificial film pattern is formed including the first side-wall insulating films.

11. The method of claim 10, comprising:
after the first sacrificial film pattern has been formed, forming a fourth insulating film covering the main surface; and
etching back the fourth insulating film to form, on the side surfaces of the first side-wall insulating films, second side-wall insulating films having a thickness, in the first direction, equal to the minimum processing dimension;
wherein the second sacrificial film pattern is formed including the first and second side-wall insulating films.

12. The method of claim 11, wherein forming the first element isolation region includes:
after the first trench has been formed, depositing the first insulating film to a thickness that fills said first trench; and
etching back the first insulating film to expose an upper surface of the second sacrificial film pattern.

13. The method of claim 12, comprising:
after the first element isolation regions have been formed, forming a plurality of closed-loop opening patterns by selectively removing the first side-wall insulating films;
forming a mask pattern covering the parts of each of the plurality of closed-loop opening patterns that extend in the first direction; and
performing etching using the mask pattern as a mask, to form third opening portions in the parts of each of the plurality of closed-loop opening patterns that are not covered by the mask pattern;
wherein forming the second trenches comprises forming the second trenches by etching bottom surfaces of the third opening portions.

14. A method of manufacturing a semiconductor device, comprising:
forming, on the main surface of a semiconductor substrate, a first sacrificial film pattern having linear first opening portions extending in a second direction in said main surface;
forming first side-wall insulating films covering the inner walls of the first opening portions;
removing the first sacrificial film pattern after the first side-wall insulating films have been formed;
forming second side-wall insulating films covering the sidewalls of the first side-wall insulating films;
forming first trenches by etching the main surface, using the first and second side-wall insulating films as a mask;
forming first element isolation regions by embedding first insulating films into the first trenches;
removing the first side-wall insulating films after the first element isolation regions have been formed;
forming second trenches by etching the regions of the main surface on which the first side-wall insulating films were formed; and
forming word lines by forming second insulating films covering the inner surfaces of the second trenches, and embedding conductive films into the second trenches.

15. The method of claim 14, wherein forming the second side-wall insulating films comprises:
after the first sacrificial film pattern has been removed, forming a plurality of island patterns by forming a fourth insulating film covering the main surface; and
forming a first mask pattern exposing the plurality of island patterns and the regions in which the first trenches are to be formed;
wherein the second side-wall insulating films are formed by etching the fourth insulating film using the first mask pattern as a mask.

16. The method of claim 14, wherein forming the second trenches comprises forming a second mask pattern covering at least the parts of the second trenches that extend in a second direction perpendicular to the first direction, within the main surface, wherein the second trenches are formed in a state in which the second mask pattern has been formed.

17. The method of claim 14, comprising embedding a fifth insulating film into the main surface to form second element isolation regions demarcating, within the main surface, a plurality of linear first active regions each extending in a second direction perpendicular to the first direction, wherein the first sacrificial film pattern is formed after the second element isolation regions have been formed.
